(19) United States
(12) Patent Application Publication
(10) Pub. No.: US 2026/0130158 A1
(43) Pub. Date: May 7, 2026

(54) SUBSTRATE BONDING APPARATUS

(71) Applicant: Samsung Electronics Co., Ltd., Suwon-si (KR)

(72) Inventors: Byeongtak Park, Suwon-si (KR); Siwoong Woo, Suwon-si (KR); Yongjoo Lee, Suwon-si, Gyeonggi-do (KR); Kyeongbin Lim, Suwon-si (KR); Jiwon Moon, Suwon-si (KR); Kazuya Ono, Suwon-si (KR); Donggap Shin, Suwon-si (KR)

(21) Appl. No.: 19/252,562

(22) Filed: Jun. 27, 2025

(30) Foreign Application Priority Data
Nov. 1, 2024 (KR) 10-2024-0153789

(51) Int. Cl. H01L 21/67; H01L 21/683; H01L 21/687

(52) U.S. Cl. CPC H10P 72/0428; H10P 72/7612; H10P 72/78

(57) ABSTRACT

An example substrate bonding apparatus includes a first bonding chuck including a first base, a deformable plate disposed on the first base and configured to support a first substrate, and a lift pin configured to apply pressure to a lower surface of the deformable plate, and a second bonding chuck including a second base configured to hold a second substrate facing the first substrate in a vertical direction.

### CROSS-REFERENCE TO RELATED APPLICATION

This application claims priority under 35 U.S.C. Korean Patent Application No. 10-2024-0153789, filed on Nov. 1, 2024, in the Korean Intellectual Property Office, the disclosure of which is incorporated by reference herein in its entirety.

### BACKGROUND

During a manufacturing process of semiconductor devices, a substrate bonding process may be performed to bond two or more substrates to each other. The substrate bonding process may be performed to improve the mounting density of semiconductor chips in the semiconductor device. For example, semiconductor modules with stacked semiconductor chips may be advantageous in shortening wiring lengths between the semiconductor chips and enabling high-speed signal processing, as well as improving the mounting density of the semiconductor chips. When manufacturing semiconductor modules having a stacked semiconductor chip structure, productivity may be increased by performing a bonding process in units of wafers and then performing a cutting process in units of stacked semiconductor chips, rather than performing a bonding process in units of semiconductor chips. The substrate bonding process may be performed in a wafer-to-wafer method in which two wafers are bonded directly without any intermediate materials. In the wafer-to-wafer method, voids may occur due to the difference in pressure caused by the difference in flow rate.

### SUMMARY

The present disclosure relates to a substrate bonding apparatus having improved reliability.

Also, the objects of the present disclosure are not limited to the aforementioned object, but other objects not described herein will be clearly understood by those skilled in the art from the following description.

In some implementations, a substrate bonding apparatus includes a first bonding chuck including a first base, a deformable plate disposed on the first base and configured to support a first substrate, and a lift pin configured to apply pressure to a lower surface of the deformable plate, a second bonding chuck including a second base configured to hold a second substrate facing the first substrate in a vertical direction, an upper pressing unit configured to apply pressure to an upper surface of the second substrate, and a picker configured to load the second substrate, and a pressure and airflow control module disposed on the deformable plate and located around an edge of the first substrate, wherein the pressure and airflow control module is configured to, when the first substrate is bonded to the second substrate, change a location at which a pressure drop near edges of the first substrate and the second substrate occurs, from a first area located in a gap between the first substrate and the second substrate to a second area located outside where an atmospheric pressure atmosphere is created.

In some implementations, a substrate bonding apparatus includes a first bonding chuck including a first base, a deformable plate disposed on the first base and configured to support a first substrate, and a lift pin configured to apply pressure to a lower surface of the deformable plate, a second bonding chuck including a second base configured to hold a second substrate facing the first substrate in a vertical direction, an upper pressing unit configured to apply pressure to an upper surface of the second substrate, and a picker configured to load the second substrate, a pressure and airflow control module disposed on the deformable plate and located around an edge of the first substrate, and a controller, wherein the pressure and airflow control module is configured to, when the first substrate is bonded to the second substrate, change a location at which a pressure drop near edges of the first substrate and the second substrate occurs, from a first area located in a gap between the first substrate and the second substrate to a second area located outside where an atmospheric pressure atmosphere is created, and increase a length of a route for gas to escape outward from between the first substrate and the second substrate, and wherein the controller is configured to, by using the pressure and airflow control module, turn on or off operation of each of the first bonding chuck and the second bonding chuck and turn on or off discharge of the gas.

In some implementations, a substrate bonding apparatus includes a first bonding chuck including a first base, a deformable plate disposed on the first base and configured to support a first substrate, and a lift pin configured to apply pressure to a lower surface of the deformable plate, a second bonding chuck including a second base configured to hold a second substrate facing the first substrate in a vertical direction, an upper pressing unit configured to apply pressure to an upper surface of the second substrate, and a picker configured to load the second substrate, a pressure and airflow control module disposed on the deformable plate and located around an edge of the first substrate, and a controller, wherein the pressure and airflow control module is configured to, when the first substrate is bonded to the second substrate, change a location at which a pressure drop near edges of the first substrate and the second substrate occurs, from a first area located in a gap between the first substrate and the second substrate to a second area located outside where an atmospheric pressure atmosphere is created, increase a length of a route for gas to escape outward from between the first substrate and the second substrate, discharge gas having a pressure condition greater than atmospheric pressure to the first area located in the gap between the first substrate and the second substrate, and discharge gas such that a flow speed of the gas decreases in the direction, in which the bonding proceeds, from a third area located in the gap between centers of the first substrate and the second substrate, and wherein a level of an upper surface of the pressure and airflow control module is higher than a level of an upper surface of the first substrate, and a vertical thickness of the pressure and airflow control module is greater than a vertical thickness of each of the first substrate and the second substrate.

### BRIEF DESCRIPTION OF THE DRAWINGS

Implementations will be more clearly understood from the following detailed description taken in conjunction with the accompanying drawings.

FIG. 1 is a schematic perspective view of an example of a substrate bonding apparatus.

FIG. 2 is a cross-sectional view of the example substrate bonding apparatus.

FIG. 3 is a cross-sectional view schematically illustrating an example of a process of operation of the substrate bonding apparatus.

FIG. 4 is a cross-sectional view schematically illustrating an example of a process of operation of the substrate bonding apparatus.

FIG. 5 is an example enlarged view of region A of FIG. 4.

FIG. 6 is a cross-sectional view schematically illustrating example airflow occurring in a gap of the substrate bonding apparatus.

FIG. 7 is a cross-sectional view schematically illustrating example airflow occurring in a gap after a pressure and airflow control module of the substrate bonding apparatus is provided.

FIG. 8 is a cross-sectional view schematically illustrating example airflow occurring in the gap after the pressure and airflow control module of the substrate bonding apparatus operates.

FIG. 9 is a flowchart illustrating an example of a method of controlling a substrate bonding apparatus.

FIG. 10 is an example flowchart illustrating detailed procedures in operation S160.

FIG. 11A is an example cross-sectional view illustrating operation S110 of FIG. 9.

FIG. 11B is an example cross-sectional view illustrating operation S120 of FIG. 9.

FIG. 11C is an example cross-sectional view illustrating operation S130 of FIG. 9.

FIG. 11D is an example cross-sectional view illustrating operation S140 of FIG. 9.

FIG. 11E is an example cross-sectional view illustrating operation S150 of FIG. 9.

FIG. 11F is an example cross-sectional view illustrating operation S161 of FIG. 10.

FIG. 11G is an example cross-sectional view illustrating operation S162 of FIG. 10.

FIG. 11H is an example cross-sectional view illustrating operation S163 of FIG. 10.

FIG. 11I is an example cross-sectional view illustrating operation S170 of FIG. 9.

### DETAILED DESCRIPTION

The implementations may have diverse changes and various forms, and thus, some implementations are illustrated in the drawings and described in detail. However, this is not intended to limit the implementations. Also, implementations described below are only examples, and thus, various changes may be made from the implementations.

All examples or illustrative terms are only used to describe the technical idea in detail, and thus, the scope of the present disclosure is not limited by these examples or illustrative terms unless limited by the claims.

As used herein, unless otherwise specified, a vertical direction may be defined as a Z direction, and a first horizontal direction and a second horizontal direction may each be defined as a horizontal direction perpendicular to the Z direction. The first horizontal direction may be referred to as an X direction and the second horizontal direction may be referred to as a Y direction. A vertical level may be referred to as a height level in the vertical direction (the Z direction). A horizontal width in the first horizontal direction may be referred to as a length in the horizontal direction (the X direction and/or the Y direction), and a vertical length may be referred to as a length in the vertical direction (the Z direction).

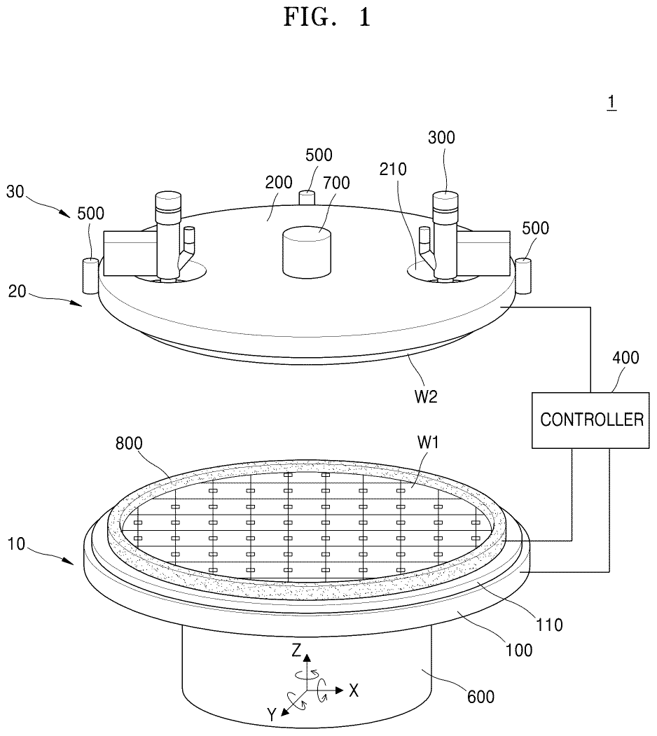

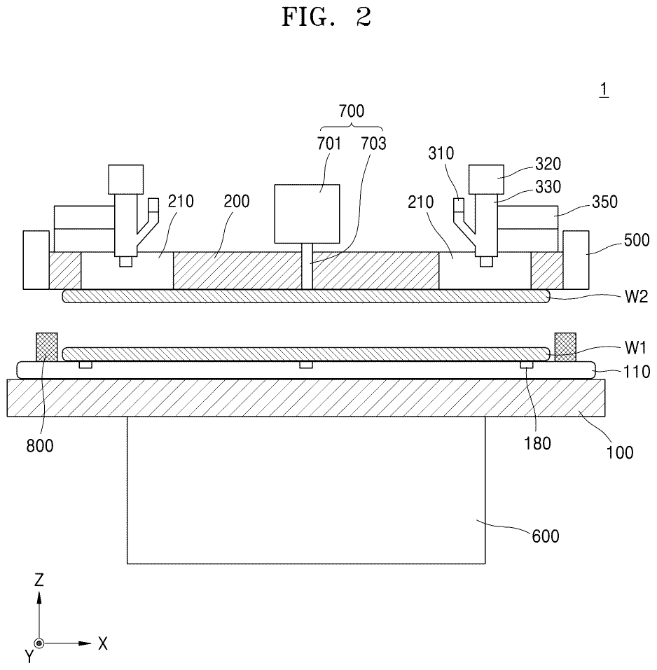

FIG. 1 is a schematic perspective view of an example of a substrate bonding apparatus 1. FIG. 2 is a cross-sectional view of the example substrate bonding apparatus 1.

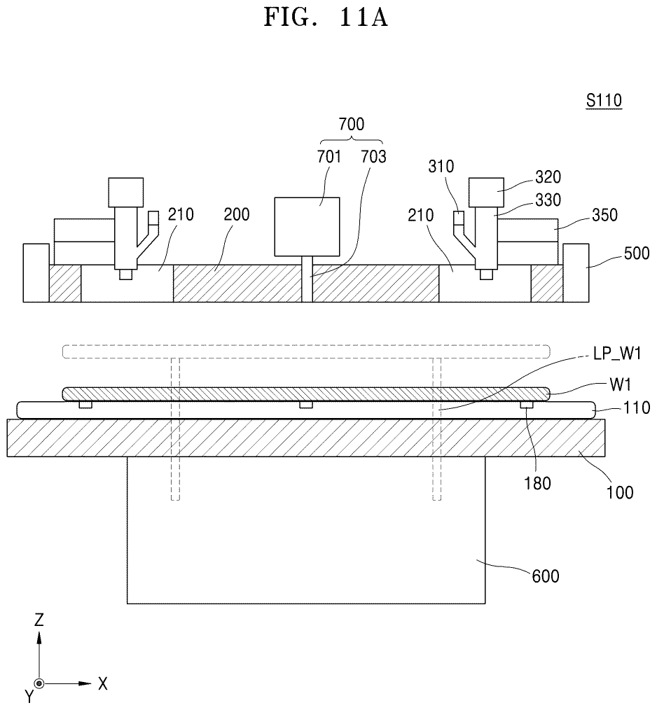

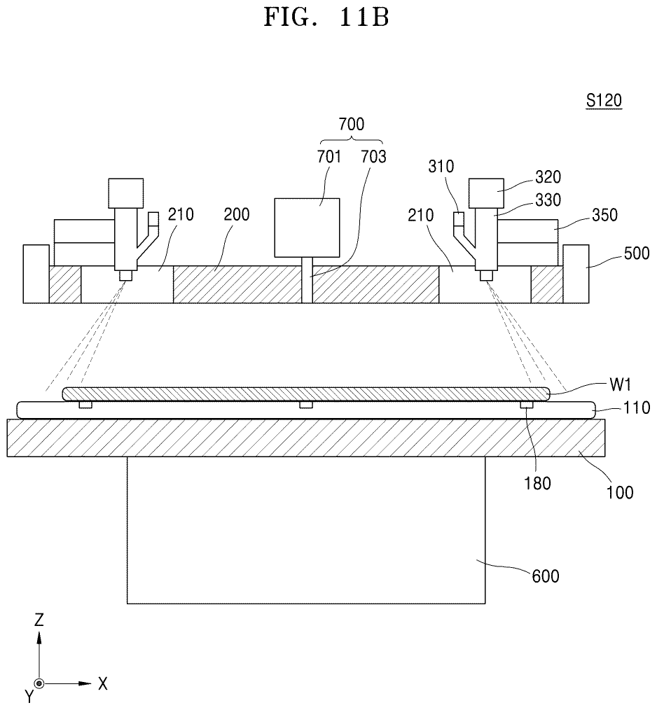

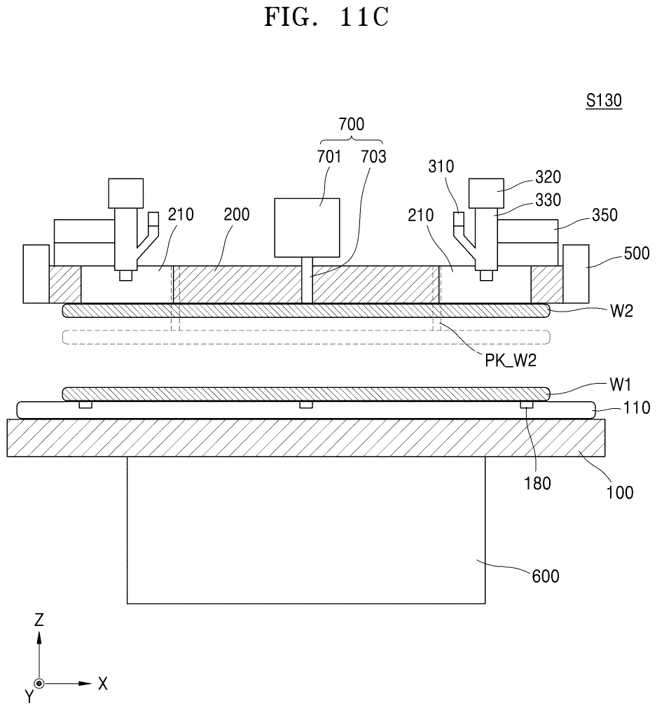

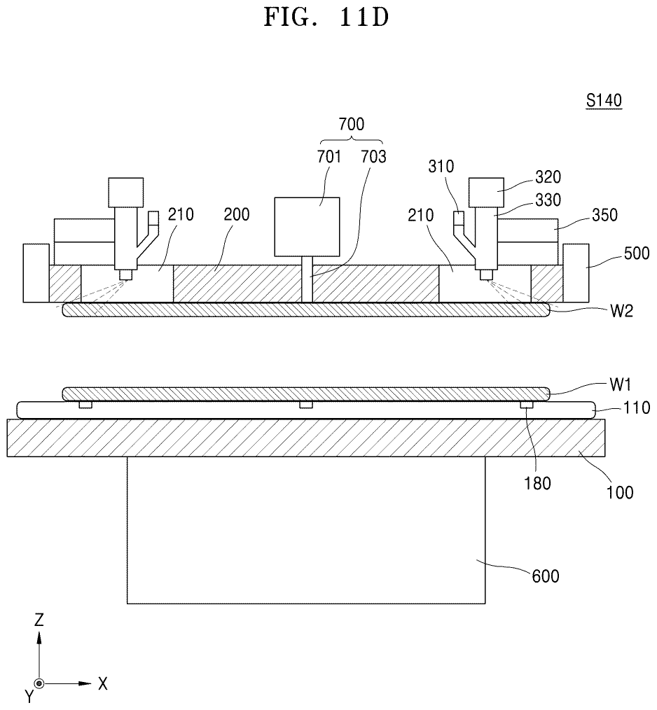

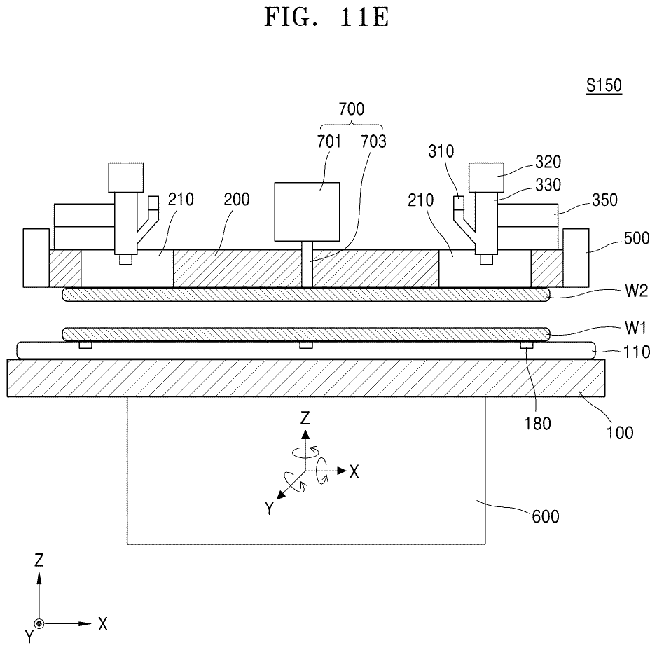

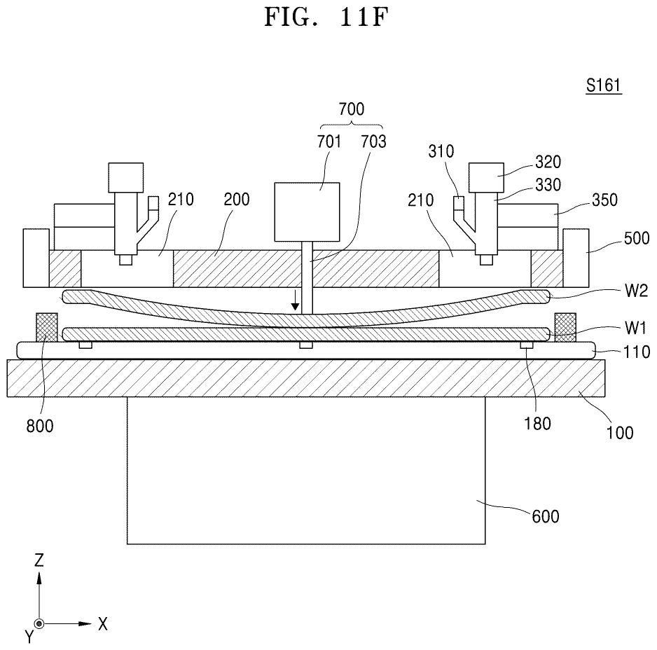

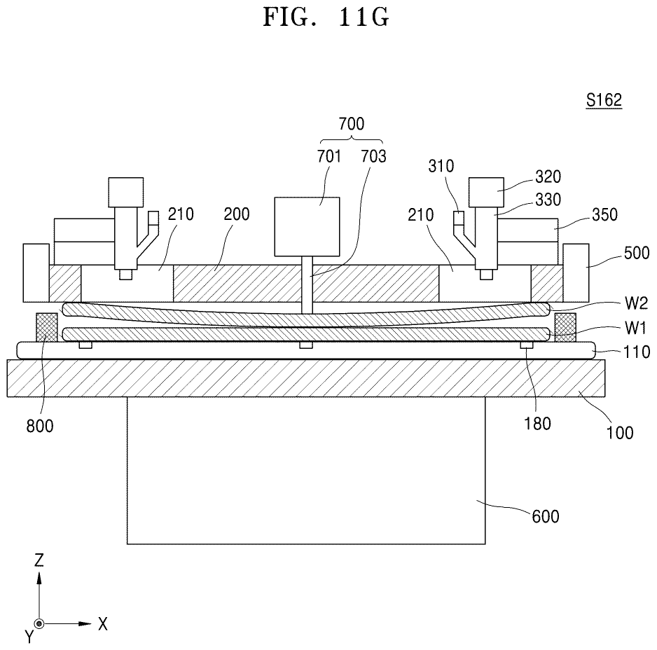

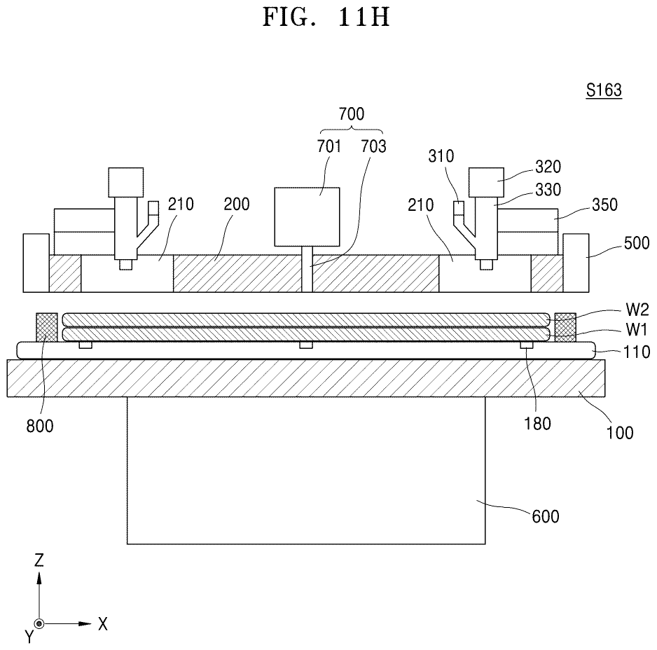

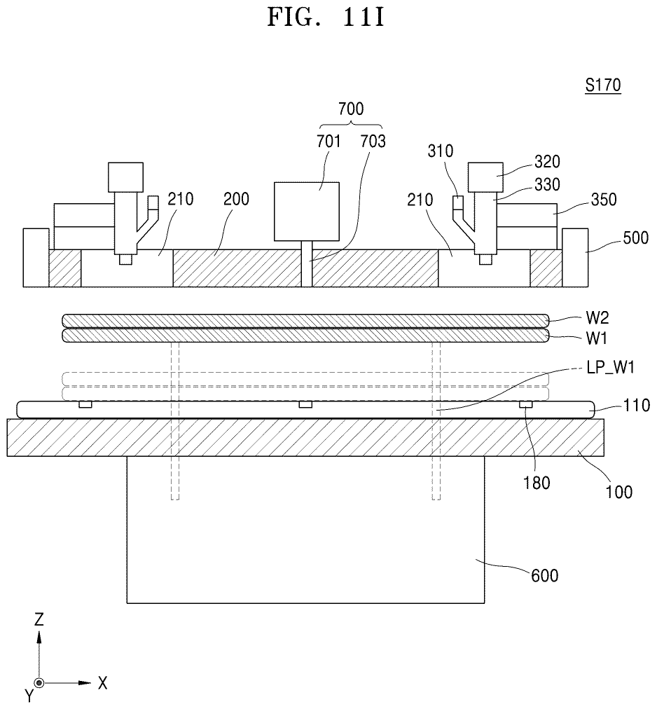

Referring to FIGS. 1 and 2, the substrate bonding apparatus 1 according to the present disclosure may include a first bonding chuck 10, a second bonding chuck 20, a lift pin LP_W1 (in FIG. 11I) as a lower pressing unit, an upper pressing unit 700, and a substrate alignment device 30.

The first bonding chuck 10 may support the lower surface of the first substrate W1. In some implementations, the lower surface of the first substrate W1 may represent an inactive surface of the first substrate W1. In the following diagrams, an X-axis direction and a Y-axis direction may be perpendicular to each other. A Z-axis direction may represent a direction perpendicular to the upper surface or the lower surface of the first substrate W1. In other words, the Z-axis direction may be a direction perpendicular to the X-Y plane.

The first substrate W1 and the second substrate W2 represent wafers and may have a circular shape in a plan view. The first substrate W1 and the second substrate W2 may include silicon. Also, the first substrate W1 and the second substrate W2 may include semiconductor elements, such as germanium, or compound semiconductors, such as silicon carbide (SiC), gallium arsenide (GaAs), indium arsenide (InAs), and indium phosphide (InP). Also, the first substrate W1 and the second substrate W2 may have a silicon on insulator (SOI) structure. In some implementations, the first substrate W1 and the second substrate W2 may include a well doped with impurities or a structure doped with impurities, which is a conductive region. Also, the first substrate W1 and the second substrate W2 may have various device isolation structures, such as a shallow trench isolation (STI) structure. Herein, it is assumed that the first substrate W1 and the second substrate W2 have a diameter of approximately 12 inches, and a case in which a silicon wafer is used as the substrate is described. However, it will be understood by those skilled in the art that a first substrate W1 and a second substrate W2 having diameters less or greater than 12 inches may be used and that the first substrate W1 and the second substrate W2 including materials other than silicon may be used.

Semiconductor device layers may be formed on active surfaces of the first substrate W1 and the second substrate W2. The semiconductor device layers may include insulating layers and/or conductive layers provided on the active surfaces of the first substrate W1 and the second substrate W2. Also, each of the semiconductor device layers may include a semiconductor device and a metal interconnect structure. The semiconductor device of the semiconductor device layer may include a memory device and a logic device.

The memory device may include a volatile memory device or a non-volatile memory device. The volatile memory devices may include, for example, volatile memory devices in existence and under development, such as dynamic random-access memory (DRAM), static RAM (SRAM), thyristor RAM (TRAM), zero capacitor RAM (ZRAM), and twin transistor RAM (TTRAM). In addition, the non-volatile memory devices may include, for example, volatile memory devices in existence and under development, such as flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, nano floating gate memory, holographic memory, molecular electronics memory, and insulator resistance change memory.

The logic device may be provided as, for example, a microprocessor, a graphics processor, a signal processor, a network processor, an audio coder-decoder (codec), a video codec, an application processor, or a system on chip, but the implementation is not limited thereto. The microprocessor may include, for example, a single core or multiple cores.

The first bonding chuck 10 may include a first base 100 and a deformable plate 110 mounted on the first base 100. The first base 100 may be disposed below the deformable plate 110 and configured to hold the outer circumferential portion of the lower surface of the deformable plate 110. In some implementations, the outer circumferential portion of the lower surface of the deformable plate 110 may be fixed to the first base 100 by using vacuum pressure, but the implementation is not limited thereto. The outer circumferential portion of the lower surface of the deformable plate 110 may be bonded to the upper surface of the first base 100, and thus, the first base 100 and the deformable plate 110 may be provided as a single body.

The first base 100 may have a lift pin LP_W1 (in FIG. 11I) as a pressing unit and holes into which the lift pin LP_W1 (in FIG. 11I) is inserted. The holes may have the same shape as the lift pin LP_W1 (in FIG. 11I).

The deformable plate 110 may be disposed on the first base 100 and support the lower surface of the first substrate W1. In some implementations, the deformable plate 110 may include a vacuum groove 180 in which a vacuum pressure is formed. The first bonding chuck 10 may hold the first substrate W1 by using the vacuum groove 180 in which the vacuum pressure is formed. In an implementation, the first bonding chuck 10 may further include a vacuum pump for applying the vacuum pressure to the vacuum groove 180. When the vacuum pressure is formed in the vacuum groove 180 by the vacuum pump, the first substrate W1 may be vacuum-adhered onto the deformable plate 110. Also, when the vacuum pressure in the vacuum groove 180 is removed by the vacuum pump, the first substrate W1 may be separated from the deformable plate 110 due to the removal of the vacuum adhesion formed by the deformable plate 110.

In some implementations, the deformable plate 110 may be configured to support the first substrate W1 by using an electrostatic force. When the deformable plate 110 is configured to hold the first substrate W1 by using the electrostatic force, the deformable plate 110 may include an electrode that receives power and generates the electrostatic force to hold the first substrate W1.

When the lift pin LP_W1 (in FIG. 11I) presses the lower surface of the deformable plate 110, the deformable plate 110 may rise. Also, the first substrate W1 may be moved in a vertical direction due to the rise of the deformable plate 110.

The thickness of the deformable plate 110 in the vertical direction Z may not be constant. In some implementations, the thickness of the central portion of the deformable plate 110 in the vertical direction Z may be different from the thickness of the outer circumferential portion thereof in the vertical direction Z.

In some implementations, the deformable plate 110 may include metal, ceramic, rubber, or a combination thereof. For example, the deformable plate 110 may include aluminum or silicon carbide (SiC).

The second bonding chuck 20 may be configured to support the second substrate W2 that faces the first substrate W1 in the vertical direction. In some implementations, the second bonding chuck 20 may face the first bonding chuck 10 in the vertical direction and hold the second substrate W2 such that the lower surface of the second substrate W2 faces the upper surface of the first substrate W1. Here, the lower surface of the second substrate W2 may represent an active surface of the second substrate W2, and the upper surface of the first substrate W1 may represent an active surface of the first substrate W1.

The second bonding chuck 20 may be located on the upper surface of the second substrate W2. That is, the second bonding chuck 20 may be spaced apart from the first bonding chuck 10 in the vertical direction with the first substrate W1 and the second substrate W2 therebetween.

The second bonding chuck 20 may include a second base 200. The second base 200 may be configured to hold the second substrate W2. In some implementations, the second base 200 may fix the upper surface of the second substrate W2 to the lower surface of the second base 200 by using the vacuum pressure. In some implementations, the second base 200 may be configured to support the second substrate W2 by using the electrostatic force. Also, the second bonding chuck 20 may include a picker PK_W2 (in FIG. 11C) configured to support the second substrate W2. A region of the picker PK_W2 (in FIG. 11C) in contact with the second substrate W2 may include a portion in which the vacuum pressure is formed, as described in the second base 200.

In at least two regions of the second base 200, observation windows 210 may extend from the upper surface to the lower surface of the second base 200. An observation window 210 may include a region for an image capturing unit 300 to capture images of the first substrate W1 and the second substrate W2. In more detail, the image capturing unit 300 may be intended to intensively capture edges of the first substrate W1 and the second substrate W2. As used herein, the edge of the substrate may correspond to an outer circumferential surface or a rim of the wafer. The observation window 210 may be formed as a hole passing through the second base 200, and thus, the upper surface of the second substrate W2 may be exposed at the bottom surface of the observation window 210. However, the observation window 210 is not limited thereto, and may have a structure in which a cover including a light-transmitting material is located in the hole.

The second base 200 may have a hole into which an upper pressing pin 703 of the upper pressing unit 700 is inserted. In some implementations, holes into which the upper pressing pin 703 of the upper pressing unit 700 is inserted may be formed in the center of the second base 200.

The upper pressing unit 700 may be configured to apply pressure to the upper surface of the second substrate W2. In some implementations, the upper pressing unit 700 may be disposed above the second bonding chuck 20 and configured to apply pressure to the center of the upper surface of the second substrate W2.

In some implementations, the upper pressing unit 700 may include the upper pressing pin 703 and an upper actuator 701 coupled to the upper pressing pin 703. The upper pressing pin 703 may pass through the hole formed in the center of the second base 200 and come into contact with the center of the upper surface of the second substrate W2. That is, the upper actuator 701 may reciprocate the upper pressing pin 703 in the vertical direction. The upper pressing pin 703 and the picker PK_W2 (in FIG. 11C) may be controlled individually.

The substrate alignment device 30 may include the image capturing unit 300 for obtaining the images of the first substrate W1 on the first bonding chuck 10 and the second substrate W2 on the second bonding chuck 20, a drive unit 600 for aligning the position of the first bonding chuck 10, and a distance sensor 500 for measuring the distance in the vertical direction Z between the first bonding chuck 10 and the second bonding chuck 20.

In some implementations, the distance sensor 500 may include a confocal sensor. In this case, although not illustrated in the diagram, the distance sensor 500 may include a light source, a lens optical system including a plurality of lenses, a beam splitter, and a detector. For example, the light source may output light for height measurement. The light for height measurement may include a plurality of components having different wavelengths (e.g., red light, green light, etc.). For example, the light for height measurement may include white light. The light for height measurement, which is output from the light source of the distance sensor 500, may be emitted onto each of the first substrate W1 and the second substrate W2 (or simply referred to as the substrates) that are reference samples, via the beam splitter and the lens optical system. The components of the light for height measurement are separated from each other according to wavelengths by the lens optical system, and the focal lengths of the components of the light for height measurement change according to the wavelengths. The reflected light for height measurement, which is reflected from each of the substrates, is received by the detector via a beam splitter and a pin hole in a barrier layer. The detector may detect the intensity of light that is incident via the pin hole. The intensity of the detected light may include height data for measuring the height of the reference sample. The detector may include a spectrometer, an imaging device such as a charge-coupled device (CCD), and/or a camera. The light in a wavelength range, which is focused on the surface of the reference sample among the components of the light for height measurement, is measured at a relatively high intensity by the detector. Therefore, the height of the surface of the reference sample may be detected by sensing light in the wavelength range that is measured at the relatively high intensity in the detector.

The image capturing unit 300 may be coupled to and disposed on the second bonding chuck 20. The image capturing unit 300 may be configured to obtain an image for alignment between the first substrate W1 and the second substrate W2.

The image capturing unit 300 may include a light source 310, a body 330, a camera 320, and a first moving stage 350. The light source 310 may be configured to emit transmissive light. The body 330 may provide a path for light to travel and include, for example, a body tube. The transmissive light emitted from the light source 310 may travel along the body 330 and be emitted from the lower end of the body 330, and the emitted light may be directed toward the second substrate W2 disposed on the second bonding chuck 20. Here, some portions of the transmissive light directed toward the second substrate W2 may pass through the second substrate W2 and be directed onto the first substrate W1.

Consequently, the transmissive light emitted by the image capturing unit 300 may pass through the second substrate W2 and be directed onto the first substrate W1. Also, measurement light reflected from the first substrate W1 may pass through the second substrate W2 and be collected by the image capturing unit 300. Thus, even if the second substrate W2 is located between the image capturing unit 300 and the first substrate W1, the image capturing unit 300 may capture the image of the first substrate W1. The image capturing unit 300 may capture images of the first substrate W1 and the second substrate W2 several times and transmit the obtained images to a controller 400.

In some implementations, the body 330 may be configured such that a path for the transmissive light emitted from the light source 310 is different from a path for the measurement light reflected from the first substrate W1 and the second substrate W2 and input to the camera 320. In some implementations, an objective lens may be located at the lower end of the body 330. A second moving stage for precisely moving the objective lens may be positioned between the body 330 and the objective lens.

The camera 320 may be configured to capture images of the first substrate W1 and the second substrate W2. The camera 320 may receive the measurement light reflected from the surfaces of the first substrate W1 and the second substrate W2. In some implementations, the camera 320 may include, but is not limited to, an infrared camera.

The first moving stage 350 may be fixed to the upper surface of the second bonding chuck 20 and move the body 330 in a first horizontal direction X and/or a second horizontal direction Y.

The drive unit 600 may be disposed below the first bonding chuck 10. The drive unit 600 may be responsible for horizontal movement, vertical movement, rotational movement, and/or tilting movement of the first bonding chuck 10. The drive unit 600 may include a six-axis stage, and may move the first bonding chuck 10 in the first horizontal direction X, the second horizontal direction Y, and the vertical direction Z or may rotate the first bonding chuck 10 about the X axis, the Y axis, and the Z axis. Therefore, the drive unit 600 may move the first bonding chuck 10, on which the first substrate W1 is disposed, and align the first substrate W1 with the second substrate W2.

The distance sensor 500 may be located around the circumference of the second bonding chuck 20 and sense a distance in the vertical direction Z between the upper surface of the first bonding chuck 10 and the lower surface of the second bonding chuck 20. In some implementations, the distance sensor 500 may measure the distance in the vertical direction Z between the first bonding chuck 10 and the second bonding chuck 20 by emitting electromagnetic waves onto the first bonding chuck 10 and analyzing the electromagnetic waves reflected therefrom. In some implementations, a plurality of distance sensors 500 may be arranged along the circumference of the second bonding chuck 20. The parallelism of the first bonding chuck 10 and the second bonding chuck 20 may be measured by the plurality of distance sensors 500. Also, the distance in the vertical direction between the first bonding chuck 10 and the second bonding chuck 20 may be measured by subtracting the thicknesses of the first substrate W1 and the second substrate W2 measured in advance from the vertical distance between the first bonding chuck 10 and the second bonding chuck 20.

The controller 400 may control the first bonding chuck 10, the second bonding chuck 20, and the substrate alignment device 30 so that the first substrate W1 is aligned with the second substrate W2. In addition, the controller 400 may control whether or not to operate a pressure and airflow control module 800, which is described below. In some implementations, the controller 400 may calculate an alignment error value of the first substrate W1 and the second substrate W2 on the basis of an alignment image of the first substrate W1 and the second substrate W2 measured from the substrate alignment device 30, and may drive the drive unit 600 to correct the alignment error value. The controller 400 may control the first bonding chuck 10 to hold or separate the first substrate W1 and control the second bonding chuck 20 to hold or separate the second substrate W2.

According to an implementation, the controller 400 may be provided as hardware, firmware, software, or any combination thereof. For example, the controller 400 may include computing devices, such as a workstation computer, a desktop computer, a laptop computer, and a tablet computer. The controller 400 may include a simple controller, a complex processor, such as a microprocessor, a central processing unit (CPU), and a graphics processing unit (GPU), a processor configured by software, dedicated hardware, or firmware. The controller 400 may be configured by, for example, a general-purpose computer, or application-specific hardware, such as a digital signal processor (DSP), a field programmable gate array (FPGA), and an application specific integrated circuit (ASIC). The controller 400 may be configured by instructions which are stored on a machine-readable medium and read and executed by one or more processors. Here, the machine-readable medium may include any mechanism for storing and/or transmitting information in a form readable by a machine (e.g., a computing device). For example, the machine-readable media may include read only memory (ROM), RAM, magnetic disk storage media, optical storage media, flash memory devices, electrical, optical, acoustic, or other forms of radio signals (e.g., carrier waves, infrared signals, digital signals, etc.), and any other signals.

The substrate bonding apparatus 1 may include a pressure and airflow control module 800. The pressure and airflow control module 800 may have a ring shape when viewed from above. The pressure and airflow control module 800 may be disposed on the upper portion of the deformable plate 110. The pressure and airflow control module 800 may surround the outer circumferential surface of the first substrate W1. In an implementation, the pressure and airflow control module 800 may be located at an edge of the first substrate W1. The controller 400 may be configured to control whether or not to operate the pressure and airflow control module 800. In an implementation, the controller 400 is configured to control on/off of the pressure and airflow control module 800, a flow speed and a flow rate of gas being discharged, and a degree of hydraulic pressure.

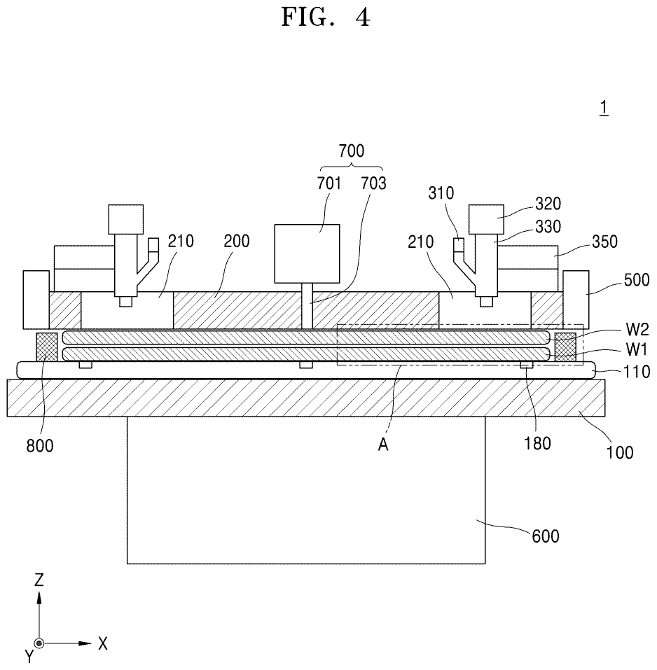

The pressure and airflow control module 800 is configured to prevent flow speed reduction and pressure drop that occur when the first substrate W1 and the second substrate W2 are brought into contact with each other at one contact point and then bonded. It will be described in more detail with reference to FIGS. 4 to 8 that the pressure and airflow control module 800 prevents the pressure drop and thus prevents voids from occurring between the first substrate W1 and the second substrate W2.

The pressure and airflow control module 800 may be disposed on the upper portion of the deformable plate 110 and is detachable therefrom. That is, the pressure and airflow control module 800 may be placed only during processes that require operations or may be placed throughout all processes. According to the present disclosure, the pressure and airflow control module 800 is described as a detachable module that is placed only when an operation is required.

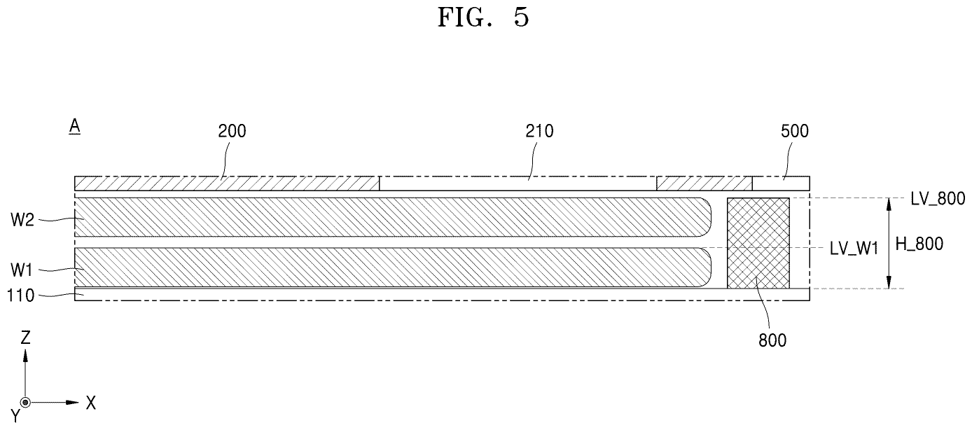

The level of the upper surface of the pressure and airflow control module 800 may not match the level of the upper surface of the first substrate W1. More specifically, the level of the upper surface of the pressure and airflow control module 800 may be higher than the level of the upper surface of the first substrate W1. The thickness of the pressure and airflow control module 800 in the vertical direction may be greater than the thickness of the first substrate W1 in the vertical direction. This is described in more detail with reference to FIG. 5.

A gas may be discharged from the inner surface of the pressure and airflow control module 800. That is, the pressure and airflow control module 800 may discharge the gas toward the central portion of the first substrate W1 in the horizontal direction. The gas discharged from the pressure and airflow control module 800 may include simple atmospheric air or atmospheric air containing helium (He). The intention of the helium may be to create an atmosphere that is typically used during a wafer bonding process.

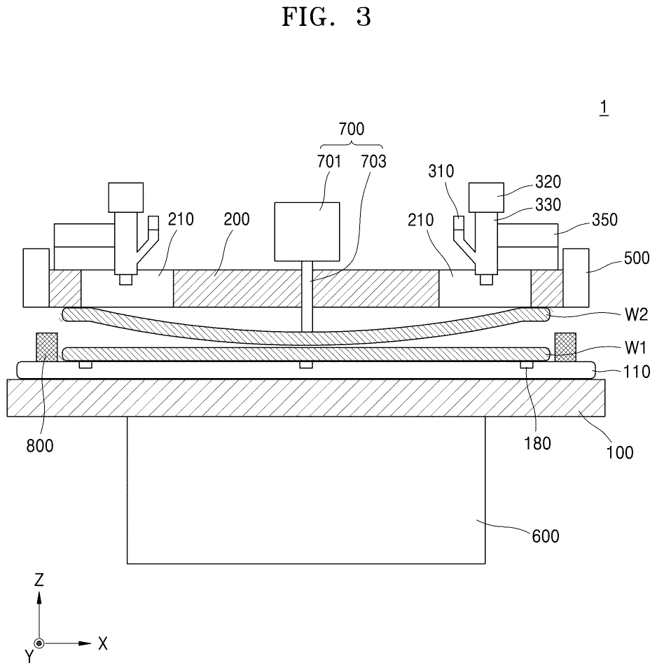

FIG. 3 is a cross-sectional view schematically illustrating an example of a process of operation of the substrate bonding apparatus 1.

The implementation is described with reference to FIG. 3 together with FIGS. 1 and 2. In order to initiate bonding between the first substrate W1 and the second substrate W2, pressure is applied to the upper surface of the second substrate W2 by using the upper pressing unit 700. Although not shown, the deformable plate 110 may also be raised by a lift pin LP_W1 (in FIG. 11A) in a lower pressing unit. The upper surface of the second substrate W2 is pressed by using the upper pressing unit 700. Here, the upper pressing unit 700 may press the center of the upper surface of the second substrate W2. As described with reference to FIGS. 1 and 2, pressing of the upper pressing unit 700 may be performed by a pressing pin and an actuator.

The upper pressing unit 700 presses the center of the upper surface of the second substrate W2. As the upper pressing unit 700 presses the center of the second substrate W2, the central region of the second substrate W2, pressed by the upper pressing unit 700, is deformed downwards into a convex shape, and thus, the first substrate W1 may come into contact with the second substrate W2 at one contact point. The one contact point may be defined as a bonding initiation point at which the bonding between the first substrate W1 and the second substrate W2 begins. For example, the bonding initiation point may represent a point at which the center of the upper surface of the first substrate W1 comes into contact with the center of the lower surface of the second substrate W2.

FIG. 4 is a cross-sectional view schematically illustrating an example of a process of operation of the substrate bonding apparatus 1.

Referring to FIG. 4 together with FIGS. 1 to 3, after the first substrate W1 and the second substrate W2 have been bonded to each other from the central portion to the outer circumferential surface of each of the substrates, the vacuum adhesion on the outer region of the second substrate W2 may be removed by the second bonding chuck 20. The outer region of the second substrate W2 may freely fall toward the outer region of the first substrate W1. The edges, which are in the outer regions of the first substrate W1 and the second substrate W2, may then be bonded to each other. When the bonding between the outer region of the first substrate W1 and the outer region of the second substrate W2 is completed, bonded substrates may be formed in which a bonding surface of the first substrate W1 and a bonding surface of the second substrate W2 are entirely bonded to each other. The pressure and airflow control module 800 may operate before or after the moment when the edges of the substrates are bonded to each other, as described above. The pressure and airflow control module 800 may also operate before the moment when the vacuum adhesion on the second substrate W2 is removed. As shown in FIG. 4, the pressure and airflow control module 800 may not be in physical contact with the edges of the first substrate W1 and the second substrate W2 and may be spaced apart therefrom.

FIG. 5 is an example enlarged view of region A of FIG. 4.

Referring to FIG. 5, the first substrate W1 and the second substrate W2 are shown as not being in completely physical contact with each other, which may be interpreted as the moment just prior to the bonding between the first substrate W1 and the second substrate W2.

A level LV_800 of the upper surface of the pressure and airflow control module 800 may be higher than a level LV_W1 of the upper surface of the first substrate W1. A thickness H_800 of the pressure and airflow control module 800 in the vertical direction may be greater than a thickness of the second substrate W2 as well as a thickness of the first substrate W1 in the vertical direction.

Although the cross-section of the pressure and airflow control module 800 is shown as a quadrangle, the shape of the cross-section of the pressure and airflow control module 800 is not limited thereto. In an implementation, the cross-section of the pressure and airflow control module 800 may not only have a rectangular shape, but may also have a square shape, a tapered shape in which the cross-section in the horizontal direction increases toward the ground, and a triangular shape.

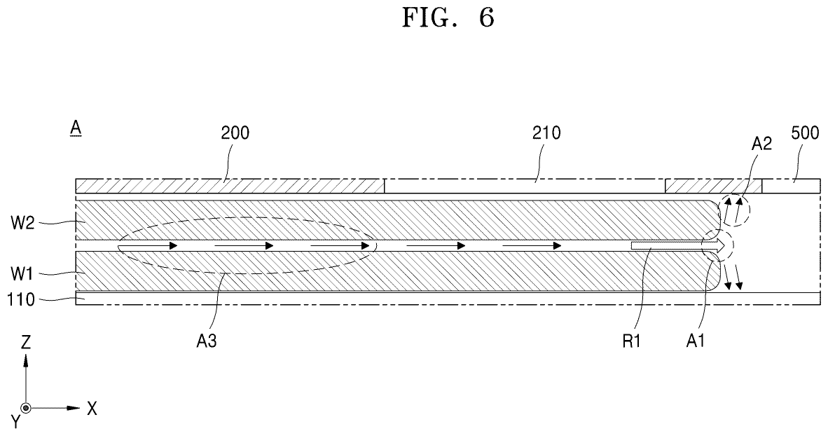

FIG. 6 is a cross-sectional view schematically illustrating example airflow occurring in a gap of the substrate bonding apparatus 1.

Referring to FIG. 6, when the first substrate W1 and the second substrate W2 are bonded to each other, the air present between the first substrate W1 and the second substrate W2 may form the airflow as shown by arrows in FIG. 6. In FIG. 6, a first area A1 may correspond to a gap near the edge of the gap between the first substrate W1 and the second substrate W2. A second area A2 is shown as an edge of the second substrate W2, but may actually correspond to an outer region of the second substrate W2 in which atmospheric pressure is formed. A third area A3 may correspond to a gap near the center of the gap between the first substrate W1 and the second substrate W2. The atmospheric air in the third area A3 may flow toward the first area A1. FIG. 6 illustrates only an edge located on the right side among edges of the first substrate W1 and the second substrate W2, and thus, the airflow in the third area A3 is illustrated as being directed only to the right side. However, the airflow in the third area A3 may also be directed to the left side and may flow toward the edge of each of the substrates.

The gas that has reached the vicinity of the first area A1 may have a size equal to the length of a first route R1 and diffuse to the outside, which is at atmospheric pressure. As gas diffuses at the end of the first route R1, the flow speed of the gas decreases rapidly. Also, as the flow speed decreases, a pressure drop may occur. As a result, the temperature drops due to the rapid pressure drop, the air at atmospheric pressure reaches the dew point, water vapor condenses, and micro-voids form. The generated micro-voids may degrade the alignment accuracy when the first substrate W1 and the second substrate W2 are bonded to each other.

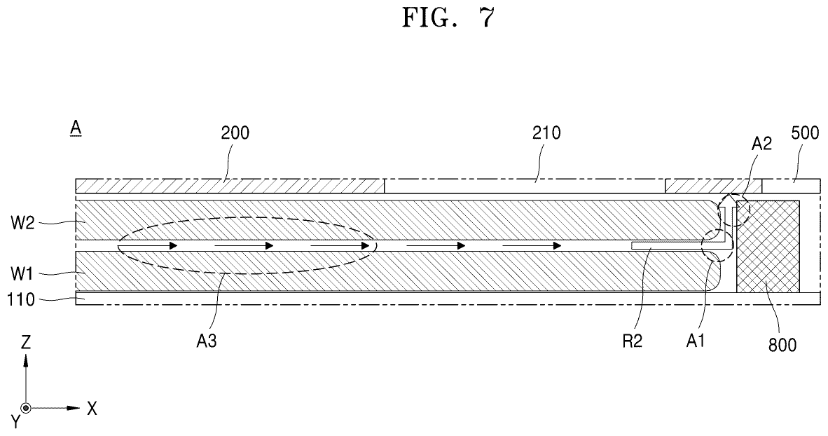

FIG. 7 is a cross-sectional view schematically illustrating example airflow occurring in a gap after the pressure and airflow control module 800 of the substrate bonding apparatus 1 is provided.

Referring to FIG. 7, the pressure and airflow control module 800 may be provided. The pressure and airflow control module 800 may be located at the edges of the first substrate W1 and the second substrate W2. In an implementation, the pressure and airflow control module 800 may be configured to change a location at which the pressure drop near the edges of the first substrate W1 and the second substrate W2 occurs, from the first area A1 located in the gap between the first substrate W1 and the second substrate W2 to the second area A2 located outside where the atmospheric pressure atmosphere is created.

The pressure and airflow control module 800 may be configured to extend a length of a route for gas to escape outward from between the first substrate W1 and the second substrate W2 to the outside. The extended route may form a second route R2. As the pressure and airflow control module 800 is located at the edge of each of the substrates, the length of the route of the gases that are located in the gap between the first substrate W1 and the second substrate W2 may increase. In an implementation, the gas that has reached the vicinity of the first area A1 may have a length equal to the length of the second route R2 and diffuse into the second area A2. Even when the pressure and airflow control module 800 is provided, the second area A2 may correspond to the outside.

The length of the second route R2 may be relatively long compared to the first route R1 of FIG. 6. As the length of the route for a gas to escape from the gap and reach a diffusion zone increases, the time for which the gas diffuses outward may increase. As a result, compressed air may be prevented from diffusing at high flow speed with respect to atmospheric pressure. Compared to FIG. 6, the high flow speed is maintained even near the edge of the second substrate W2. Due to the high flow speed, the pressure drop generated in FIG. 6 may be prevented, and thus, the temperature drop may be prevented. Also, the temperature drop is prevented, and thus, the gases located in the gap are prevented from reaching the dew point. Consequently, micro-voids are prevented from forming.

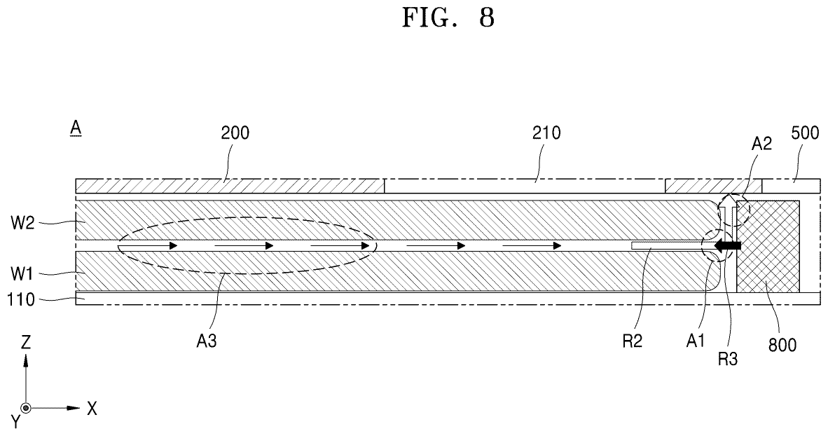

In FIG. 7, the micro-voids may be prevented from being generated only by arranging the pressure and airflow control module 800 at the edge of each of the substrates to increase the length of the route for the gases to escape from the gap. However, a controller may also cause the pressure and airflow control module 800 to discharge the gas from the gap between the first substrate W1 and the second substrate W2. This is described in more detail with reference to FIG. 8.

FIG. 8 is a cross-sectional view schematically illustrating example airflow occurring in the gap after the pressure and airflow control module 800 of the substrate bonding apparatus 1 operates.

Referring to FIG. 8, the controller may cause the pressure and airflow control module 800 to discharge the gas into the first area A1 that is the gap between the first substrate W1 and the second substrate W2. In an implementation, the pressure of the gas discharged from the pressure and airflow control module 800 may be greater than atmospheric pressure. In an implementation, the pressure condition of the gas discharged from the pressure and airflow control module 800 may be greater than the atmospheric pressure by as much as about 20 kPa to about 80 kPa.

The pressure and airflow control module 800 may discharge the gas to the first area A1, but the gas discharged by the pressure and airflow control module 800 may reach the third area A3. Whether the pressure and airflow control module 800 discharges the gas or not may be turned on or off by the controller. The flow rate, the hydraulic pressure, and the flow speed of the gas discharged from the pressure and airflow control module 800 may be controlled by the controller.

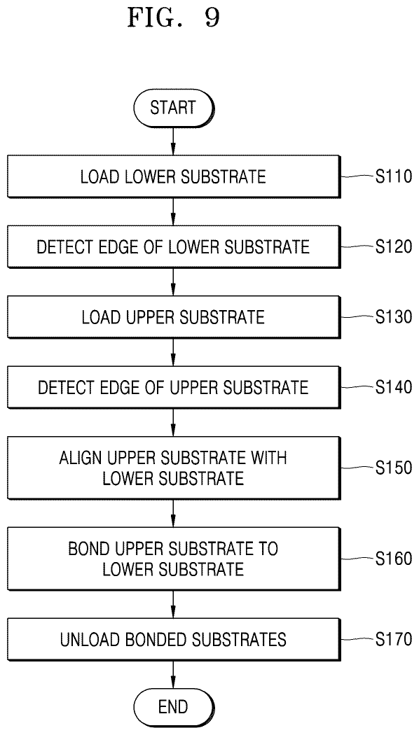

FIG. 9 is a flowchart illustrating an example of a method of controlling a substrate bonding apparatus 1.

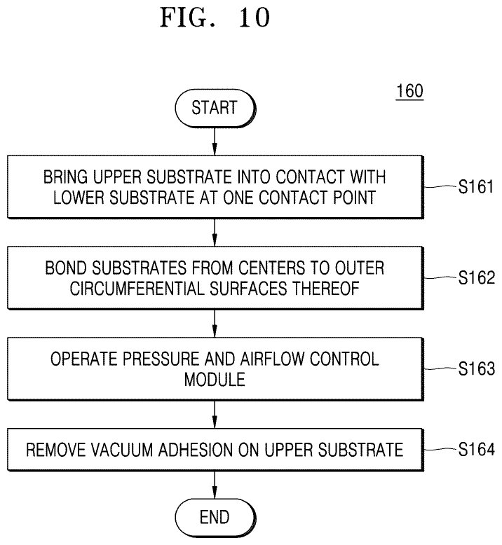

The implementation is described with reference to FIG. 9 together with FIGS. 1 to 8. A lower substrate described with reference to FIGS. 9 and 10 may correspond to the first substrate W1 described above. An upper substrate described with reference to FIGS. 9 and 10 may correspond to the second substrate W2 described above.

The method of controlling the substrate bonding apparatus 1 may include operation S110 of loading the lower substrate. The lower substrate may be loaded onto a first bonding chuck 10.

The method of controlling the substrate bonding apparatus 1 may include operation S120 of detecting an edge of the lower substrate after the lower substrate has been loaded in operation S110. Operation S120 of detecting the edge of the lower substrate may be performed by an image capturing unit 300.

The method of controlling the substrate bonding apparatus 1 may include operation S130 of loading the upper substrate after performing operation S120. The upper substrate may be loaded onto a second bonding chuck 20.

The method of controlling the substrate bonding apparatus 1 may include operation S140 of detecting an edge of the upper substrate after the upper substrate has been loaded in operation S130. Operation S140 of detecting the edge of the upper substrate may be performed by the image capturing unit 300. By performing up to operation S140, the edges of the upper and lower substrates may be detected to determine the locations of the upper and lower substrates.

The method of controlling the substrate bonding apparatus 1 may include operation S150 of aligning the upper and lower substrates with each other after the detection of the edges of the upper and lower substrates is complete. Operation S150 may be performed by driving a drive unit 600 on the basis of the data obtained by performing up to operation S140. The operation of the drive unit 600 is described in detail with reference to FIGS. 1 and 2 and is thus omitted below.

The method of controlling the substrate bonding apparatus 1 may include operation S160 of bonding the upper and lower substrates to each other after the alignment of the upper and lower substrates is terminated by operation S150. The detailed procedures in operation S160 are described in more detail with reference to FIG. 10. Finally, the method of controlling the substrate bonding apparatus 1 may include operation S170 of unloading bonded substrates when the bonding of the upper and lower substrates is complete.

FIG. 10 is an example flowchart illustrating detailed procedures in operation S160.

Referring to FIG. 10 together with FIGS. 1 to 9, operation S160 may include operation S161 of bringing the lower substrate and the upper substrate into contact with each other at one contact point. According to the present disclosure, the one contact point at which the lower substrate and the upper substrate first come into contact with each other may correspond to the central portion of each of the substrates.

Operation S160 may include, after operation S161, operation S162 of bonding the upper substrate and the lower substrate from the central portion to the outer circumferential surface of each of the substrates. The outer circumferential surface of each of the substrates of FIG. 10 may correspond to the edge of the substrate described above.

Operation S160 may include, after operation S162, operation S163 of operating the pressure and airflow control module 800. Although operation S163 is shown as being performed after operation S162, the pressure and airflow control module 800 may operate at the moment when the bonding is in progress from the central portion to the outer circumferential surface of the substrate, and thus, operation S163 may be performed simultaneously with operation S162.

Last, operation S160 may include, after operation S163, operation S164 of removing vacuum adhesion on the upper substrate. As described with reference to FIGS. 3 and 4, the edge of the upper substrate may be bonded to the edge of the lower substrate by removing the vacuum adhesion on the upper substrate. Therefore, operation S164 of FIG. 10 may be performed simultaneously with operation S163.

FIG. 11A is an example cross-sectional view illustrating operation S110 of FIG. 9.

Referring to FIG. 11A together with FIGS. 1 and 10, the lower substrate, which is the first substrate W1, may be loaded onto the upper surface of the deformable plate 110 by the lift pin LP_W1 in operation S110. The lift pin LP_W1 may be operated by a lower actuator, which is omitted in the diagram, and the lower actuator may be controlled by the controller.

In some implementations, a lower outer pressing member may include the lift pin LP_W1 and an actuator. The lift pin LP_W1 may have a cylindrical shape extending in the vertical direction Z. The lift pin LP_W1 may pass through a hole formed in the outer region of the first base 100 and come into contact with the lower outer region of the deformable plate 110.

The actuator may drive the lift pin LP_W1 up and down. That is, the actuator may reciprocate the lift pin LP_W1 in the vertical direction Z. In some implementations, the actuator may include a stacked piezoelectric actuator, a voice coil motor, a rack-and-pinion coupled to a motor, or the like.

A plurality of lift pins LP_W1 may be arranged, and although only two are shown in the diagram, the number of lift pins LP_W1 is not limited thereto.

FIG. 11B is an example cross-sectional view illustrating operation S120 of FIG. 9. FIG. 11C is an example cross-sectional view illustrating operation S130 of FIG. 9. FIG. 11D is an example cross-sectional view illustrating operation S140 of FIG. 9. FIG. 11E is an example cross-sectional view illustrating operation S150 of FIG. 9.

Referring to FIG. 11B, in operation S120, the camera 320 of an image capturing unit may detect the edge of the first substrate W1. The edge of the first substrate W1 may have a rounded shape. In operation S120, the camera 320 may detect the edge, particularly the positions on the edge in the horizontal direction and the vertical direction. Referring to FIG. 11C, in operation S130, the second substrate W2 may be loaded onto the second bonding chuck 20 by the picker PK_W2. The picker PK_W2 may pass through a hole formed in the outer region of the second base 200 in the same manner as the lift pin. The picker PK_W2 may create a negative pressure at the end thereof and thus adhere to the second substrate W2, or may include a separate arm capable of gripping the second substrate W2 although not shown in the drawings. Referring to FIG. 11D, in operation S140, the camera 320 of the image capturing unit may detect the edge of the second substrate W2. The edge of the second substrate W2 may have a rounded shape. In operation S140, the camera 320 may detect the edge, particularly the positions on the edge in the horizontal direction and the vertical direction.

Referring to FIG. 11E, the drive unit 600 may be driven to align the first substrate W1 with the second substrate W2 in operation S150. The drive unit 600 may be responsible for horizontal movement, vertical movement, rotational movement, and/or tilting movement of the first bonding chuck 10. The drive unit 600 may include a six-axis stage, and may move the first bonding chuck 10 in the first horizontal direction X, the second horizontal direction Y, and the vertical direction Z or may rotate the first bonding chuck 10 about the X axis, the Y axis, and the Z axis. Therefore, the drive unit 600 may move the first bonding chuck 10, on which the first substrate W1 is disposed, and align the first substrate W1 with the second substrate W2.

FIG. 11F is an example cross-sectional view illustrating operation S161 of FIG. 10. FIG. 11G is an example cross-sectional view illustrating operation S162 of FIG. 10. FIG. 11H is an example cross-sectional view illustrating operation S163 of FIG. 10. FIG. 11I is an example cross-sectional view illustrating operation S170 of FIG. 9.

Referring to FIG. 11F, the upper pressing unit 700 may be operated to apply pressure to the upper surface of the second substrate W2. More specifically, the upper pressing unit 700 may press the center of the upper surface of the second substrate W2. The second substrate W2 pressed by the upper pressing unit 700 may be deformed as shown in FIG. 11F, and the first substrate W1 may come into contact with the second substrate W2 at one contact point in the central portion thereof. Starting with the contacting in operation S161, the bonding process between the first substrate W1 and the second substrate W2 may proceed. From operation S161, the pressure and airflow control module 800 may be provided. Referring to FIG. 11G, the second bonding chuck 20 is lowered by operation S162, and as a result, bonding may be performed not only at the central portion of each of the substrates, but also from the central portion to the edge, which is the outer circumferential surface, of each of the substrates. From operation S162, the pressure and airflow control module 800 may operate. Referring to FIG. 11H, the vacuum adhesion may be removed from the second substrate W2 such that the second substrate W2 is separated from the second bonding chuck 20, and the bonding process between the first substrate W1 and the second substrate W2 may be completed.

Finally, when the bonding between the first substrate W1 and the second substrate W2 is complete, the substrates that have been bonded together may be unloaded by operation S170. When unloaded by operation S170, the substrates may be separated from the deformable plate 110 by raising of the lift pin LP_W1. Also, the first substrate W1 and the second substrate W2 raised by the lift pin LP_W1 may be moved in the horizontal direction and unloaded from the substrate bonding apparatus 1 by a transfer robot.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A substrate bonding apparatus comprising:
a first bonding chuck comprising a first base, a deformable plate, and a lift pin, the deformable plate being disposed on the first base and being configured to support a first substrate, and the lift pin being configured to apply pressure to a lower surface of the deformable plate;
a second bonding chuck comprising a second base, an upper pressing unit, and a picker, the second base being configured to hold a second substrate facing the first substrate in a vertical direction, the upper pressing unit being configured to apply pressure to an upper surface of the second substrate, and the picker being configured to load the second substrate; and
a pressure and airflow control circuit disposed on the deformable plate and located around an edge of the first substrate,
wherein the pressure and airflow control circuit is configured to, based on the first substrate being bonded to the second substrate, change a pressure drop location from a first area to a second area, the pressure drop location being a location at which a pressure drop occurs near at least one edge of the first substrate and the second substrate based on the first substrate being bonded to the second substrate, the first area being located in a gap between the first substrate and the second substrate, and the second area being configured to have atmospheric pressure.

2. The substrate bonding apparatus of claim 1, wherein the pressure and airflow control circuit is configured to increase a length of a route for gas to escape between the first substrate and the second substrate.

3. The substrate bonding apparatus of claim 1, wherein the pressure and airflow control circuit is configured to discharge gas having a pressure condition greater than the atmospheric pressure to the first area.

4. The substrate bonding apparatus of claim 3, wherein the gas being discharged from the pressure and airflow control circuit has the pressure condition that is greater than the atmospheric pressure by about 20 kPa to about 80 kPa.

5. The substrate bonding apparatus of claim 1, wherein a level of an upper surface of the pressure and airflow control circuit is higher than a level of an upper surface of the first substrate.

6. The substrate bonding apparatus of claim 1, wherein a vertical thickness of the pressure and airflow control circuit is greater than a first vertical thickness of the first substrate and a second vertical thickness of the second substrate.

7. The substrate bonding apparatus of claim 1, wherein a direction of bonding between the first substrate and the second substrate extends from a center of the first substrate to an edge of the first substrate and from a center of the second substrate to an edge of the second substrate, and
wherein the pressure and airflow control circuit is configured to discharge gas from a third area to thereby decrease a flow speed of the discharged gas in the direction, the third area being located in a gap between the center of the first substrate and the center of the second substrate.

8. The substrate bonding apparatus of claim 1, comprising a controller,
wherein the controller is configured to, using the pressure and airflow control circuit, turn gas discharge on or off.

9. The substrate bonding apparatus of claim 8, wherein the pressure and airflow control circuit is configured to operate based on bonding between the first substrate and the second substrate being performed from a center of the first substrate to an outer circumferential surface of the first substrate and from a center of the second substrate to an outer circumferential surface of the second substrate.

10. The substrate bonding apparatus of claim 1, wherein gas being discharged from the pressure and airflow control circuit comprises helium (He).

11. A substrate bonding apparatus comprising:
a first bonding chuck comprising a first base, a deformable plate, and a lift pin, the deformable plate being disposed on the first base and being configured to support a first substrate, and the lift pin being configured to apply pressure to a lower surface of the deformable plate;
a second bonding chuck comprising a second base, an upper pressing unit, and a picker, the second base being configured to hold a second substrate facing the first substrate in a vertical direction, the upper pressing unit being configured to apply pressure to an upper surface of the second substrate, and the picker being configured to load the second substrate;
a pressure and airflow control circuit disposed on the deformable plate and located around an edge of the first substrate; and
a controller,
wherein the pressure and airflow control circuit is configured to, based on the first substrate being bonded to the second substrate,
change a pressure drop location from a first area to a second area, the pressure drop location being a location at which a pressure drop occurs near at least one edge of the first substrate and the second substrate, the first area being located in a gap between the first substrate and the second substrate, and the second area being configured to have atmospheric pressure, and
increase a length of a route for gas to escape between the first substrate and the second substrate, and
wherein the controller is configured to, using the pressure and airflow control circuit, turn a first operation of the first bonding chuck and a second operation of the second bonding chuck on or off and to turn gas discharge on or off.

12. The substrate bonding apparatus of claim 11, wherein the pressure and airflow control circuit is configured to discharge gas having a pressure condition greater than the atmospheric pressure to the first area, and
wherein the gas being discharged from the pressure and airflow control circuit has the pressure condition that is greater than the atmospheric pressure by about 20 kPa to about 80 kPa.

13. The substrate bonding apparatus of claim 11, wherein a level of an upper surface of the pressure and airflow control circuit is higher than a level of an upper surface of the first substrate, and
wherein a vertical thickness of the pressure and airflow control circuit is greater than a first vertical thickness of the first substrate and a second vertical thickness of the second substrate.

14. The substrate bonding apparatus of claim 11, wherein a direction of bonding between the first substrate and the second substrate extends from a center of the first substrate to an edge of the first substrate and from a center of the second substrate to an edge of the second substrate, and
wherein the pressure and airflow control circuit is configured to discharge gas from a third area to thereby decrease a flow speed of the discharged gas in the direction, the third area being located in a gap between the center of the first substrate and the center of the second substrate.

15. The substrate bonding apparatus of claim 11, wherein the pressure and airflow control circuit is configured to operate based on bonding between the first substrate and the second substrate being performed from a center of the first substrate to an outer circumferential surface of the first substrate and a center of the second substrate to an outer circumferential surface of the second substrate.

16. The substrate bonding apparatus of claim 11, comprising an image capturing circuit disposed above the second bonding chuck,
wherein the image capturing circuit is configured to obtain an alignment image for the first substrate and the second substrate.

17. The substrate bonding apparatus of claim 16, wherein the image capturing circuit comprises:
a light source;
a body;
a camera; and
a first moving stage.

18. The substrate bonding apparatus of claim 11, comprising a driver coupled to a lower portion of the first bonding chuck and configured to adjust a position of the lift pin.

19. A substrate bonding apparatus comprising:
a first bonding chuck comprising a first base, a deformable plate, and a lift pin, the deformable plate being disposed on the first base and being configured to support a first substrate, and the lift pin being configured to apply pressure to a lower surface of the deformable plate;
a second bonding chuck comprising a second base, an upper pressing unit,, and a picker, the second base being configured to hold a second substrate facing the first substrate in a vertical direction, the upper pressing unit being configured to apply pressure to an upper surface of the second substrate, and the picker being configured to load the second substrate;
a pressure and airflow control circuit disposed on the deformable plate and located around an edge of the first substrate; and
a controller,
wherein the pressure and airflow control circuit is configured to, based on the first substrate being bonded to the second substrate,
change a pressure drop location from a first area to a second area, the pressure drop location being a location at which a pressure drop occurs near at least one edge of the first substrate and the second substrate, the first area being located in a gap between the first substrate and the second substrate, and the second area being configured to have atmospheric pressure,
increase a length of a route for gas to escape between the first substrate and the second substrate,
discharge gas having a pressure condition greater than the atmospheric pressure to the first area, and
discharge gas from a third area to thereby decrease a flow speed of the discharged gas in a direction of bonding between the first substrate and the second substrate extends, the third area being located in a gap between a center of the first substrate and a center of the second substrate, and
wherein a level of an upper surface of the pressure and airflow control circuit is higher than a level of an upper surface of the first substrate, and
wherein a vertical thickness of the pressure and airflow control circuit is greater than a first vertical thickness of the first substrate and a second vertical thickness of the second substrate.

20. The substrate bonding apparatus of claim 19, wherein the controller is configured to, using the pressure and airflow control circuit, turn a first operation of the first bonding chuck and a second operation of the second bonding chuck on or off and to turn gas discharge on or off, and
wherein the pressure and airflow control circuit is configured to operate based on the bonding between the first substrate and the second substrate being performed from the center of the first substrate to an outer circumferential surface of the first substrate and from the center of the second substrate to an outer circumferential surface of the second substrate.
